(19) United States
(12) Patent Application Publication
(10) Pub. No.: US 2008/0122544 A1
(43) Pub. Date: May 29, 2008

(54) JITTER SMOOTHING FILTER

(75) Inventor: Ping-Ying Wang, Hsinchu City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 11/563,225

(22) Filed: Nov. 27, 2006

(51) Int. Cl. H03L 7/00; G06F 1/04; H03L 7/06

(52) U.S. Cl. 331/17; 327/291; 327/157

(57) ABSTRACT

A jitter smoothing filter receives a direction signal and a phase error signal having a pulse width representing a phase error signal. The jitter smoothing filter generates an up proportional control signal and a down proportional control signal for driving a charge pump. For each pulse in the phase error signal, the jitter smoothing filter generates at least two pulses in the up or down proportional control signal. The number of pulses generated by the jitter smoothing filter depends on the pulse width of the corresponding pulse in the pulse error signal.

### BACKGROUND OF THE INVENTION

1. Field of the Invention

The invention relates to a filter, and in particular to a digital jitter smoothing filter.

2. Description of the Related Art

Please refer to FIG. 1. FIG. 1 shows a block diagram of a conventional digital phase locked loop (DPLL) 100. The DPLL 100 comprises a digital phase detector 110, a digital gain multiplier 120, a digital delta-sigma modulator 130, first and second digital-to-time converters 140 and 150, a first charge pump 160, a loop filter 170, a second charge pump 180, and a voltage controlled oscillator (VCO) 190. The digital phase detector 110 detects the phase difference between a reference clock and a feedback clock and generates a phase error value ERR_{PD}, wherein the feedback clock is generated by the VCO 190. The digital phase detector 110 further generates a direction signal DIR indicates the up or down direction. The digital gain multiplier 120 adjusts the gain of the phase error value ERR_{PD}, and the digital delta-sigma modulator 130 suppresses noise. The first digital-to-time converter 140 enables an “iup” or “idn” integral control signal for the first charge pump 160, according to whether the feedback clock is lagging or leading the reference clock. If the first charge pump 160 receives the integral up control signal “iup”, current is driven into the loop filter 170; otherwise, if the first charge pump 160 receives the integral down control signal “idn”, current is drawn from the loop filter 170. Similarly, the second digital-to-time converter 150 enables a “pup” or “pdn” proportional control signal for the second charge pump 180, according to whether the feedback clock is lagging or leading the reference clock. The loop filter 170 outputs a first control voltage VBN which is used to adjust the VCO 190. Similarly, the second charge pump 180 outputs a second control voltage VBP, which is also used to adjust the VCO 190. The VCO 190 generates the feedback clock having a frequency controlled by the control voltages VBN and VBP.

The signal generated by the DPLL circuit sometimes has unwanted shifting of the edge from its ideal position, this is typically called jitter. The jitter is a variation of the frequency or phase of successive cycles in the output signal. Various factors like input frequency of the reference clock, the loop bandwidth, etc., contribute to the jitter. For example, when there are fluctuations in the reference signal caused by power supply noise, a large cycle to cycle jitter is induced accordingly. To increase DPLL circuit performance, an anti-jitter circuit to reduce the level of jitter in the signal.

### BRIEF SUMMARY OF THE INVENTION

A detailed description is given in the following embodiments with reference to the accompanying drawings.

A jitter smoothing filter receives a direction signal and a phase error signal having a pulse width representing a phase error value. The jitter smoothing filter generates an up proportional control signal and a down proportional control signal for driving a charge pump according to the phase error signal. For each pulse in the phase error signal, the jitter smoothing filter generates at least two pulses in the up or down proportional control signal. The number of pulses generated by the jitter smoothing filter depends on the pulse width of the corresponding pulse in the pulse error signal.

In some embodiments, the jitter smoothing filter comprises first and second operating units, and first and second pulse generators, for processing an up direction and a down direction respectively. The direction signal indicates the up or down direction, for example, a high state (1) indicates an up direction, and a low state (0) indicates a down direction, in some embodiments, the direction may be represented by an up signal and a down signal. The first operating unit generates an up phase error signal from the phase error signal by masking with a clock signal and the direction signal (or the up signal). The first pulse generator receives the up phase error signal and generates at least two pulses in the up proportional control signal for each pulse in the phase error signal. The second operating unit generates a down phase error signal from the phase error signal by masking with the clock signal and an inverse of the direction signal (or the down signal). The second pulse generator receives the down phase error signal and generates at least two pulses in the down proportional control signal for each pulse in the phase error signal. The number of pulse in the up proportional control signal or down proportional control signal depends on the pulse width of the phase error signal.

A jitter smoothing method for driving a charge pump comprising receiving a phase error signal and a direction signal, and generating at least two pulses in an up proportional control signal or down proportional control signal for each pulse in the phase error signal. The up or down proportional control signal is for increasing or decreasing the frequency of a voltage controlled oscillator (VCO). The control signal output from the jitter smoothing filter increases or decreases the frequency of the VCO by a small unit at each cycle of a clock signal, in order to avoid a rapid and significant change in frequency, which causes a large cycle to cycle jitter, and may result in component failure.

### BRIEF DESCRIPTION OF THE DRAWINGS

The invention can be more fully understood by reading the subsequent detailed description and examples with references made to the accompanying drawings, wherein:

FIG. 1 shows a block diagram of a conventional digital phase locked loop;

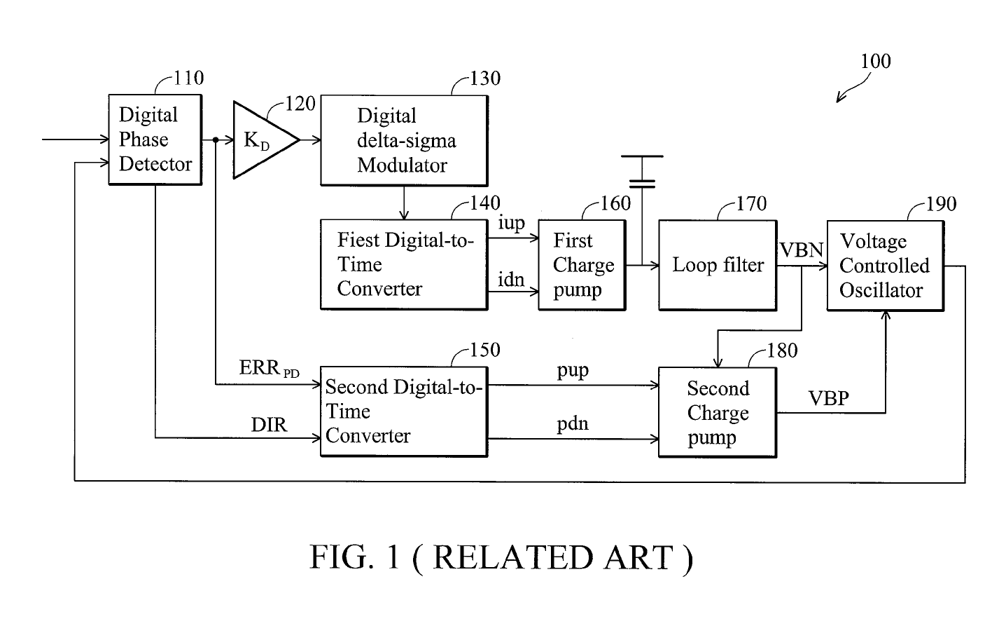

FIG. 2 shows a block diagram of an embodiment of a digital phase locked loop;

FIG. 3 shows a block diagram of an exemplary jitter smoothing filter shown in FIG. 2;

FIG. 4 shows a timing diagram illustrating the operation of the jitter smoothing filter shown in FIG. 3;

FIG. 5 shows a block diagram of another embodiment of a digital phase locked loop;

FIG. 6 shows a block diagram of the jitter smoothing filter shown in FIG. 5;

FIG. 7 illustrates an embodiment of a pulse generator.

### DETAILED DESCRIPTION OF THE INVENTION

The description is made for the purpose of illustrating the general principles of the invention and should not be taken in a limiting sense. The scope of the invention is best determined by reference to the appended claims.

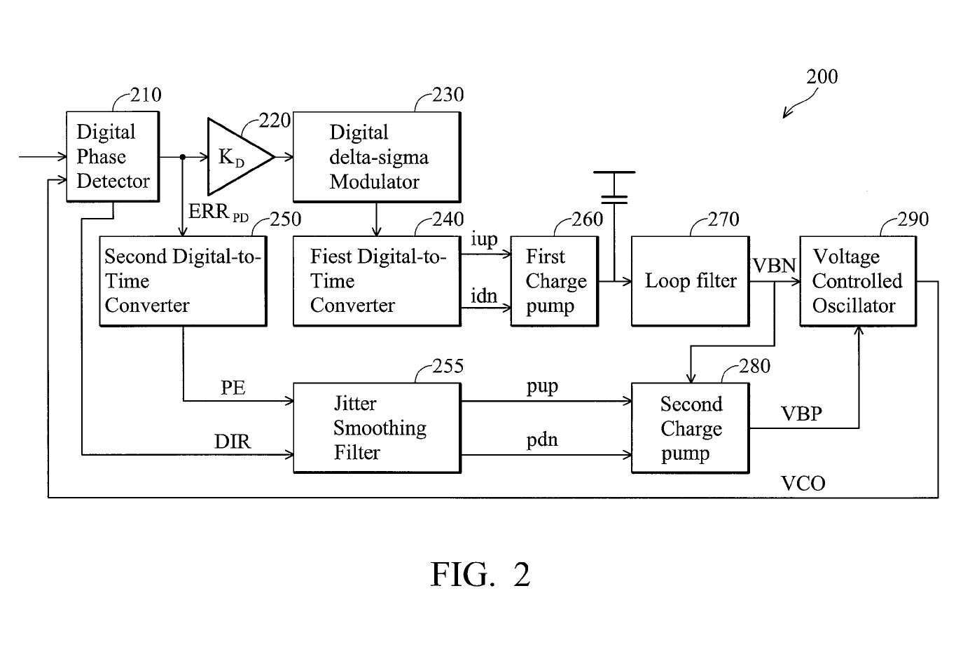

Please refer to FIG. 2. FIG. 2 shows a block diagram of a digital phase locked loop (DPLL) according to an embodiment of the invention. The key difference with the conventional DPLL is that a jitter smoothing filter 255 is further added to reduce the jitter induced in the clock signal generated by the voltage controlled oscillator. The second digital-to-time converter 250 converts the phase error value ERR_{PD} in digital domain to the phase error signal PE in time domain. The jitter smoothing filer 255 enables a “pup” or “pdn” proportional control signal for controlling the second charge pump 280. A detailed description of the jitter smoothing filer 255 is provided in the following.

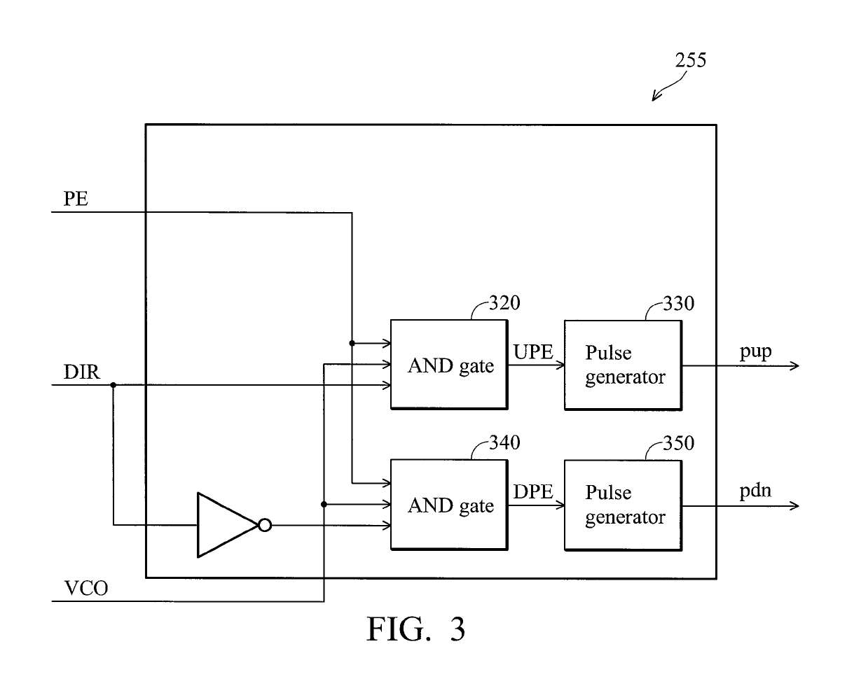

Please refer to FIG. 3. FIG. 3 shows a block diagram of the jitter smoothing filter 255 shown in FIG. 2. The jitter smoothing filer 255 comprises AND gates 320 and 340, and pulse generators 330 and 350. A direction signal DIR is generated from the digital phase detector 210. When the feedback clock lags the reference clock, the direction signal DIR is in a high state (1), which shows an up direction for controlling the charge pump. The AND gate 320 masks the phase error signal PE with the direction signal DIR and a clock signal to generate an up phase error signal UPE, in this embodiment, the clock signal is the feedback clock generated by the voltage controlled oscillator VCO 290 shown in FIG. 2. In some other embodiments, the clock signal has a clock frequency of N times the feedback clock frequency. The up phase error signal UPE is sent to the pulse generator 330 to generate an up proportional control signal “pup”. Similarly, when the feedback clock leads the reference clock, the direction signal DIR is in a low state (0), which shows a down direction for controlling the charge pump. The AND gate 340 masks the phase error signal PE with an inverse of the direction signal DIR and the feedback clock to generate a down phase error signal DPE. The down phase error signal DPE is sent to the pulse generator 350 to generate a down proportional control signal “pdn”.

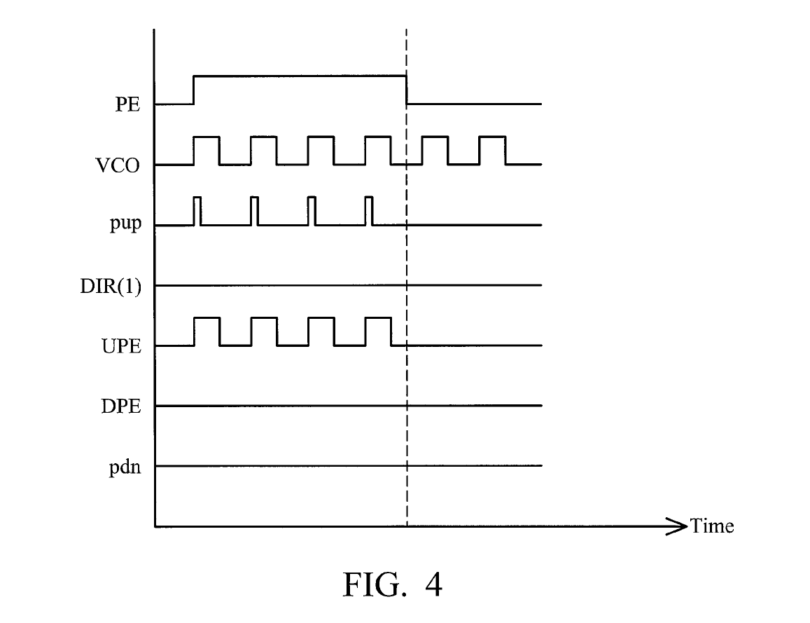

FIG. 4 shows a timing diagram illustrating the operation of the jitter smoothing filter 255 shown in FIG. 3. The phase error signal PE from the second digital-to-time converter 250 (see FIG. 2) represents the lag quantity or lead quantity depending on whether the direction signal DIR is carrying a down direction (0) or up direction (1). In this figure, assume that the feedback clock lags the reference clock and hence the direction signal DIR is in a high state (1). The AND gate 320 generates an up phase error signal UPE from the PE signal, feedback clock, and direction signal. The pulse generator 320 generates an up proportional control signal pup having a narrower pulse width than the up phase error signal UPE. In this embodiment shown in FIG. 4, the PE signal has a pulse width of approximately 4 feedback clock cycles, therefore, both the up phase error signal UPE and up proportional control signal pdn have 4 corresponding pulses. The longer the PE pulse width, the more pulses in the up/down proportional control signal generated by the jitter smoothing filter 255. In other words, the jitter smoothing filter converts a single pulse in the PE signal into multiple pulses for driving the charge pump. In the related art, the phase error signal masking with the direction signal or the inverse of the direction signal (depending on the control direction for the charge pump) is directly utilized to drive the charge pump. Once a big difference between the reference clock and feedback clock suddenly occurs, the phase error value ERR_{PD} becomes large and the digital-to-time converter 150 generates a long pulse in one of the output (pup or pdn) for the second charge pump 180. This single long pulse for driving the charge pump has a high probability of inducing jitter due to the big change in the VCO frequency. The jitter smoothing methods and jitter smoothing filters provided in the present invention diminish the jitter by feeding many short pulses to the charge pump, and hence the VCO frequency is adjusted in a step wise manner.

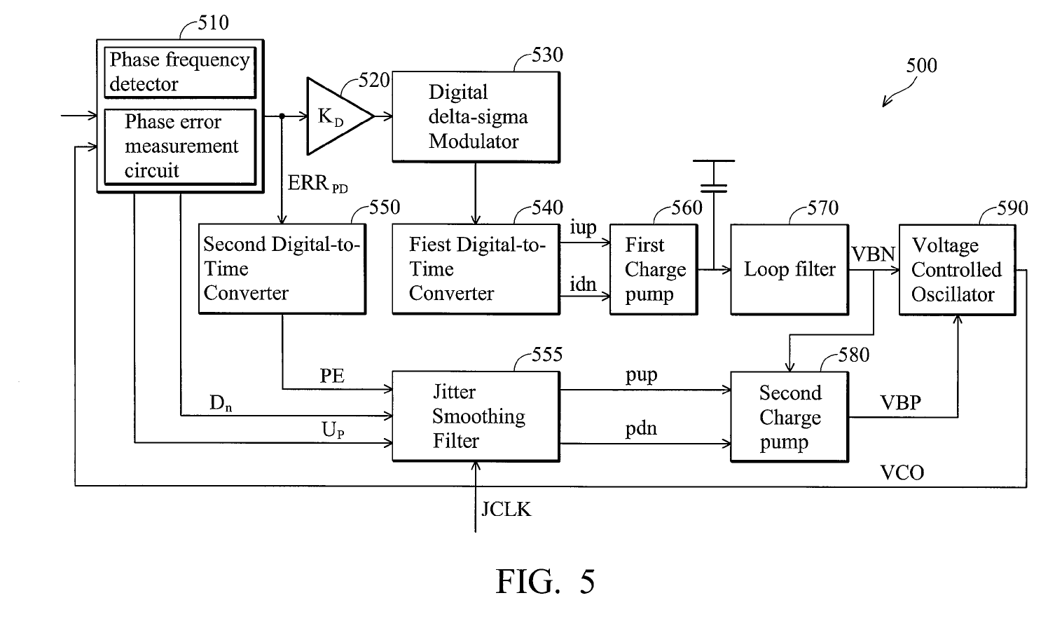

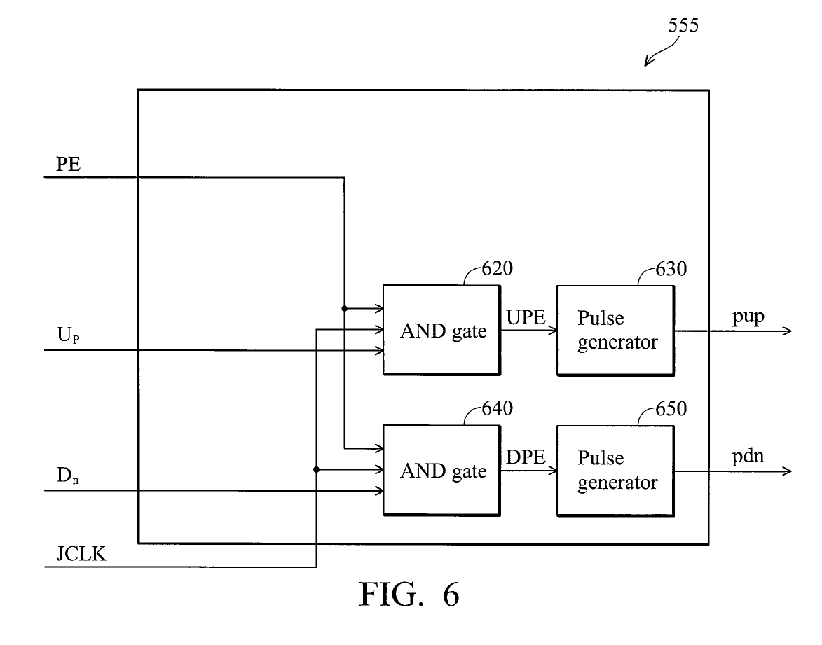

Please refer to FIG. 5 and FIG. 6 at the same time. FIG. 5 shows a block diagram of another embodiment of a digital phase locked loop 500. FIG. 6 shows a block diagram of the jitter smoothing filter 555 shown in FIG. 5. In the previous embodiment, the feedback clock VCO is taken as the clock signal to be masked with the phase error signal PE. In this embodiment, another clock signal JCLK is chosen to be taken as the masked clock signal. In FIGS. 5 and 6, two signals Up and Dn instead of a single direction signal DIR are provided to the jitter smoothing filter 555. The digital phase detector may comprise a phase frequency detector and a phase error measurement circuit.

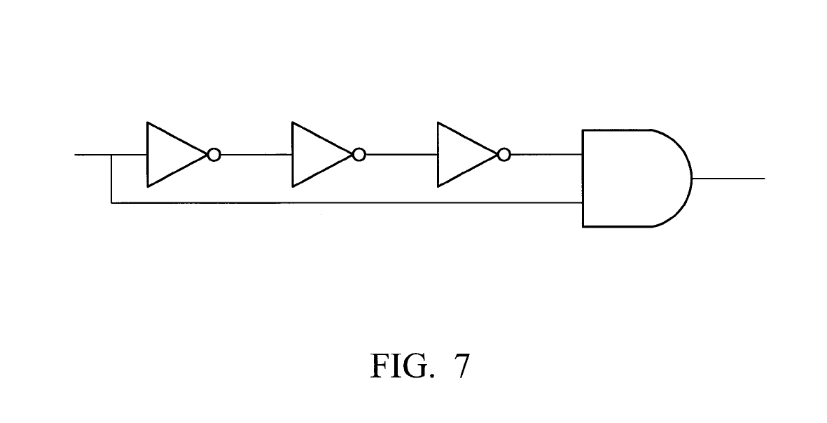

FIG. 7 illustrates an embodiment of the pulse generator 330, 350, 630, or 650. The pulse generator comprises an AND gate and three cascaded inverters (NOT gates). Note that the number of inverters may be any odd number, and the total delay of these inverters determines the pulse width of the output of the pulse generator. The input of the pulse generator is either an up phase error signal or a down phase error signal, which carries a period of clock like pulses. The purpose of the pulse generator is to adjust the width of the pulses utilizing the delay of the cascaded inverters, so the greater the number of inverters, the wider the pulse width. An alternative is to replace an even number of inverters by a delay circuit, but please note that the total delay should not be longer than a cycle of the clock signal.

Compared with the related art, the jitter smoothing filter of the invention controls the charge pump by feeding a plurality of short pulses, so that the VCO frequency is adjusted by a small unit at each cycle of a predetermined clock signal, thus achieving jitter smoothing for the DPLL circuit. The DPLL implementing the jitter smoothing filter may achieves the benefits of low manufacturing cost, stable input frequency tracking, low short term jitter for narrow loop bandwidth design, and high bandwidth setting for low input frequency.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A jitter smoothing filter receiving a direction signal and a phase error signal having a pulse width representing a phase error value, and generating an up proportional control signal and a down proportional control signal for driving a charge pump, characterized in that:
for each pulse in the phase error signal, at least two pulses in the up or down proportional control signal are generated, wherein the number of pulses in the up or down proportional control signal generated by the jitter smoothing filter depends on the pulse width of the corresponding pulse in the pulse error signal.

2. The jitter smoothing filter as claimed in claim 1, comprising:
a first operating unit for generating an up phase error signal from the phase error signal by masking with a clock signal and the direction signal;
a first pulse generator coupled to the first operating unit for receiving the up phase error signal and generating a pulse in the up proportional control signal for each cycle of the up phase error signal;
a second operating unit for generating a down phase error signal from the phase error signal by masking with the clock signal and an inverse of the direction signal; and
a second pulse generator coupled to the second operating unit for receiving the down phase error signal and generating a pulse in the down proportional control signal for each cycle of the down phase error signal.

3. The jitter smoothing filter as claimed in claim 2, wherein the first operating unit is an AND gate for performing AND operations on the clock signal, the direction signal, and the phase error signal; the second operating unit is an AND gate for performing AND operations on the clock signal, the inverse of the direction signal, and the phase error signal.

4. The jitter smoothing filter as claimed in claim 2, wherein the first or second pulse generator comprises an AND gate and an odd number of cascaded inverters.

5. The jitter smoothing filter as claimed in claim 2, wherein the clock signal is a feedback clock output from a voltage controlled oscillator (VCO) controlled by the charge pump.

6. The jitter smoothing filter as claimed in claim 1, wherein the direction signal comprises an up signal and a down signal, and the jitter smoothing filter comprising:
a first operating unit for generating an up phase error signal from the phase error signal by masking with a clock signal and the up signal;
a first pulse generator coupled to the first operating unit for receiving the up phase error signal and generating a pulse in the up proportional control signal for each cycle of the up phase error signal;
a second operating unit for generating a down phase error signal from the phase error signal by masking with the clock signal and the down signal; and
a second pulse generator coupled to the second operating unit for receiving the down phase error signal and generating a pulse in the down proportional control signal for each cycle of the down phase error signal.

7. A jitter smoothing method for driving a charge pump, comprising:
receiving a phase error signal and a direction signal; and
generating at least two pulses in an up proportional control signal or down proportional control signal for each pulse in the phase error signal;
wherein the up or down proportional control signal is for increasing or decreasing a frequency of a voltage controlled oscillator (VCO) by a small unit at each cycle of a clock signal.

8. The jitter smoothing method as claimed in claim 7, further comprising:
generating an up phase error signal from the phase error signal by masking with the clock signal and the direction signal;
generating the up proportional control signal by adjusting the pulse width of the up phase error signal;
generating a down phase error signal from the phase error signal by masking with the clock signal and an inverse of the direction signal; and
generating the down proportional control signal by adjusting the pulse width of the down phase error signal.

9. The jitter smoothing method as claimed in claim 8, wherein the clock signal is a feedback clock output from the VCO.

10. The jitter smoothing method as claimed in claim 7, wherein the direction signal comprises an up signal and a down signal, and the method further comprising:
generating an up phase error signal from the phase error signal by masking with the clock signal and the up signal;
generating the up proportional control signal by adjusting the pulse width of the up phase error signal;
generating a down phase error signal from the phase error signal by masking with the clock signal and the down signal; and
generating the down proportional control signal by adjusting the pulse width of the down phase error signal.
